(19) United States
(12) Patent Application Publication
(10) Pub. No.: US 2024/0006170 A1
(43) Pub. Date: Jan. 4, 2024

(54) SEMICONDUCTOR PROCESS APPARATUS AND POWER CONTROL METHOD

(71) Applicant: BEIJING NAURA MICROELECTRONICS EQUIPMENT CO., LTD., Beijing (CN)

(72) Inventors: Jing WEI, Beijing (CN); Gang WEI, Beijing (CN); Jing YANG, Beijing (CN); Guodao SHAN, Beijing (CN)

(21) Appl. No.: 18/254,062

(22) PCT Filed: Nov. 25, 2021
(86) PCT No.: PCT/CN2021/133048

§ 371 Date: May 23, 2023

(30) Foreign Application Priority Data
Nov. 27, 2020 (CN) 202011358299.X

(51) Int. Cl. H01J 37/32

(52) U.S. Cl. CPC H01J 37/3299; H01J 37/32715; H01J 2237/2007

(57) ABSTRACT

The present disclosure provides a semiconductor process apparatus and a power control method. The apparatus includes an upper electrode assembly, a process chamber, and a power adjustment assembly. A chuck configured to carry a wafer is arranged in the process chamber. The upper electrode assembly is configured to excite the process gas in the process chamber to form the plasma. The power adjustment component is configured to detect the bias voltage value on the upper surface of the chuck in real-time, calculate the difference between the bias voltage value and the target bias voltage value, and when the difference is greater than the preset threshold, adjust the output power value of the upper electrode assembly according to the difference until the difference is less than or equal to the preset threshold. The semiconductor process apparatus of the present disclosure can be configured to more precisely control the plasma density in the process chamber to improve the process consistency among different process chambers.

### TECHNICAL FIELD

The present disclosure generally relates to the semiconductor process apparatus field and, more particularly, to a semiconductor process apparatus and a power control method.

### BACKGROUND

With the rapid development of the manufacturing process of semiconductor devices, requirements for the performance and integration of devices become higher and higher, which makes plasma technology widely used. In a plasma etching or deposition system, by introducing various reaction gases such as chlorine (Cl₂), sulfur hexafluoride (SF₆), octafluorocyclobutane (C₄F₈), Oxygen (O₂), etc., the bound electrons in the gas atoms overcome the potential well and become free electrons by an external electromagnetic field (DC or AC). The free electrons that obtain kinetic energy collide with molecules, atoms, or ions to completely dissociate the gas and form a plasma. The plasma includes a large number of active particles such as electrons, ions (including positive and negative ions), excited atoms, molecules, and free radicals. These active particles interact with the surface of the wafer placed in the chamber and are exposed to the plasma, which makes the surface of the wafer material have various physical and chemical reactions to change the properties of the material surface to finish etching or another process. In the development of the plasma apparatus applied for the semiconductor manufacturing process, the most important factor is to increase the processing capacity for the wafer to increase throughput, and the ability to perform the manufacturing process of a highly integrated device.

As a feature size of an integrated circuit continues to decrease, the requirements for the processing process also become more and more strict. One of the important requirements is the consistency of etched products. During the process, strict requirements are imposed on the consistency of the process results of all chambers of the same type of machine to avoid the process risks caused by the consistency problems of the chambers. Thus, the consistency of the process results can be realized by strict process control for different chambers.

However, in the existing semiconductor process apparatus, the consistency between different process chambers is poor, and differences between the plasma densities generated in the different process chambers are difficult to be eliminated, which causes product quality unstable.

### SUMMARY

The present disclosure aims to provide a semiconductor process apparatus and a power control method, which can more accurately control the plasma density in a process chamber to improve the process consistency among different process chambers.

To realize the above purpose, the present disclosure provides a semiconductor process apparatus, including an upper electrode assembly, a process chamber, and a power adjustment assembly. The process chamber is provided with a chuck configured to carry a wafer.

The upper electrode assembly is configured to excite a process gas in the process chamber to form a plasma.

The power adjustment assembly is configured to detect a bias voltage value on an upper surface of the chuck in real-time, calculate a difference between the bias voltage value and a target bias voltage value, and when the difference is greater than a preset threshold, adjust output power of the upper electrode assembly according to the difference until the difference is less than or equal to the preset threshold.

In some embodiments, the power adjustment assembly includes a voltage comparator and a voltage sensor.

The voltage sensor is configured to detect the bias voltage value on the upper surface of the chuck in real-time and transfer the bias voltage value to the voltage comparator.

The voltage comparator is configured to calculate the difference between the bias voltage value and the target bias voltage value, and when the difference is greater than the preset threshold, compare the bias voltage value to the target bias voltage value, if the bias voltage value is lower than the target bias voltage value, reduce the output power of the upper electrode assembly, if the bias voltage value is higher than the target bias voltage value, increase the output power value of the upper electrode assembly, and when the difference is less than or equal to the preset threshold, maintain the output power of the upper electrode assembly unchanged.

In some embodiments, an adjustment amplitude of the output power of the upper electrode assembly adjusted by the voltage comparator and the difference between the bias voltage value and the target bias voltage value are positively correlated.

In some embodiments, the voltage comparator is configured to determine the adjustment amplitude corresponding to the difference according to a difference interval corresponding to the difference and a preset correspondence between the difference interval and the adjustment amplitude and adjust the output power of the upper electrode assembly according to the adjustment amplitude.

In some embodiments, the correspondence between the difference interval and the adjustment amplitude includes:
a first difference interval, the difference being greater than or equal to 50% of the target bias voltage value;
a second difference interval, the difference being greater than or equal to 20% of the target bias voltage value and less than 50% of the target bias voltage value;
a third difference interval, the difference being greater than or equal to 5% of the target bias voltage value and less than 20% of the target bias voltage value; and
a fourth difference interval, the difference being greater than or equal to 1% of the target bias voltage value and less than 5% of the target bias voltage value.

A first adjustment amplitude corresponding to the first difference interval is larger than a second adjustment amplitude corresponding to the second difference interval. The second adjustment amplitude is larger than a third adjustment amplitude corresponding to the third difference interval. The third adjustment amplitude is greater than a fourth adjustment amplitude corresponding to the fourth difference interval.

In some embodiments, the first adjustment amplitude is greater than or equal to 50 W, the second adjustment amplitude is greater than or equal to 20 W, the third adjustment amplitude is greater than or equal to 5 W, and the fourth adjustment amplitude is greater than or equal to 5 W. The amplitude is greater than or equal to 1 W.

In some embodiments, the preset threshold is 1% of the target bias voltage value.

In some embodiments, when the upper surface of the chuck is an upper surface made of a ceramic material layer, the voltage sensor is configured to detect an RF voltage value of the ceramic material layer in real-time and convert the RF voltage value into the bias voltage value according to a correspondence between the RF voltage value and the bias voltage value.

In some embodiments, when the upper surface of the chuck is an upper surface made of a metal layer, the voltage sensor is configured to detect a DC voltage of the upper surface of the metal layer in real-time, the DC voltage being the bias voltage value.

In some embodiments, the power adjustment assembly further includes an analog-to-digital converter. The analog-to-digital converter is configured to convert the bias voltage value transferred by the voltage sensor in an analog signal into a digital signal and transfer the digital signal to the voltage comparator.

As another technical solution, the present disclosure further provides a power control method, applied to the semiconductor process apparatus of embodiments of the present disclosure. The power control method includes:
after the upper electrode assembly excites the process gas in the process chamber to form the plasma, detecting the bias voltage value on the upper surface of the chuck in real-time; and
calculating the difference between the bias voltage value and the target bias voltage value, and when the difference is greater than the preset threshold, adjusting the output power value of the upper electrode assembly according to the difference until the difference is less than or equal to the preset threshold.

In some embodiments, calculating the difference between the bias voltage value and the target bias voltage value, and when the difference is greater than the preset threshold, adjusting the output power of the upper electrode assembly according to the difference until the difference is less than or equal to the preset threshold includes:
calculating the difference between the bias voltage value and the target bias voltage value, and when the difference is greater than the preset threshold, comparing the bias voltage value to the target bias voltage value, if the bias voltage value is lower than the target bias voltage value, reducing the output power of the upper electrode assembly, if the bias voltage value is higher than the target bias voltage value, increasing the output power of the electrode assembly, when the difference is less than or equal to the preset threshold, maintaining the output power value of the upper electrode assembly unchanged.

In some embodiments, the adjustment amplitude for adjusting the output power of the upper electrode assembly and the difference between the bias voltage value and the target bias voltage value are positively correlated.

In some embodiments, the adjustment amplitude corresponding to the difference is determined according to the difference interval corresponding to the difference and the preset correspondence between the difference interval and the adjustment amplitude. The output power of the upper electrode assembly is adjusted according to the adjustment amplitude.

In some embodiments, the correspondence between the difference interval and the adjustment amplitude includes:
the first difference interval, the difference being greater than or equal to 50% of the target bias voltage value;
the second difference interval, the difference being greater than or equal to 20% of the target bias voltage value and less than 50% of the target bias voltage value;
the third difference interval, the difference being greater than or equal to 5% of the target bias voltage value and less than 20% of the target bias voltage value; and
the fourth difference interval, the difference being greater than or equal to 1% of the target bias voltage value and less than 5% of the target bias voltage value.

The first adjustment amplitude corresponding to the first difference interval is larger than the second adjustment amplitude corresponding to the second difference interval. The second adjustment amplitude is larger than the third adjustment amplitude corresponding to the third difference interval. The third adjustment amplitude is greater than the fourth adjustment amplitude corresponding to the fourth difference interval.

In the technical solutions of the semiconductor process apparatus and the power control method of embodiments of the present disclosure, the power adjustment assembly can detect the bias voltage value on the upper surface of the chuck in real-time, calculate the difference between the bias voltage value and the target bias voltage value, determine whether the plasma density in the current process chamber is normal by determining whether the difference exceeds the preset threshold, and automatically adjust the output power value of the upper electrode assembly according to the difference when the difference is greater than the preset threshold. Therefore, in embodiments of the present disclosure, the density state of the plasma can be characterized by detecting the bias voltage value. Feedback adjustment can be performed in real-time to accurately control the plasma density in the semiconductor process and compensate for the difference caused by inconsistency of hardware such as coils and dielectric windows. Thus, process consistency can be improved among different process chambers.

### BRIEF DESCRIPTION OF THE DRAWINGS

The accompanying drawings are used to provide a further understanding of the present disclosure and form a part of the specification. The accompanying drawings are used to explain the present disclosure with embodiments below and do not limit the present disclosure.

FIG. 1 illustrates a schematic structural diagram of a semiconductor process apparatus according to an embodiment of the present disclosure.

FIG. 2 illustrates a schematic flowchart of a power control method according to an embodiment of the present disclosure.

### DETAILED DESCRIPTION OF THE EMBODIMENTS

Specific embodiments of the present disclosure are described in detail below with reference to the accompanying drawings. It should be understood that the specific embodiments described here are only used to illustrate and explain the present disclosure, but not to limit the present disclosure.

After research, the inventor of the present disclosure found that the main reason for the poor consistency of the process chambers in the existing semiconductor process apparatus is differences existing between coils, dielectric windows, and other hardware of different process chambers in the existing semiconductor process apparatus. For example, for an inductively coupled plasma apparatus, an RF current flowing through the coil is usually indirectly controlled by controlling an RF parameter of plasma discharging. However, due to a nonlinear characteristic of a plasma impedance and impacts of an uncertain factor such as coil processing and installation, the RF current flowing through the coil and the RF power loaded by the power supply may not have a one-to-one correspondence. Among different process chambers, even if the RF power loaded by the power supply is the same, the current on the coil cannot be completely consistent. Thus, with an adjustment solution of changing the coil current by controlling the RF power loaded by the power supply, consistency of the plasma parameters and repeatability of the process can be difficult to be ensured.

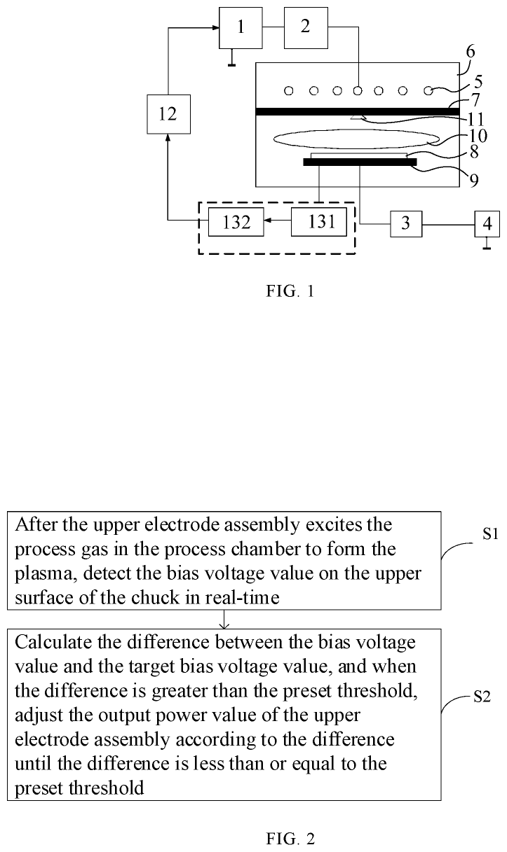

To solve the above technical problem, the present disclosure provides a semiconductor process apparatus, as shown in FIG. 1. The semiconductor process apparatus includes an upper electrode assembly, a process chamber 6, and a power adjustment assembly. The process chamber 6 includes a chuck 9 configured to carry a wafer (e.g., an electrostatic chuck, i.e., Echuck).

The upper electrode assembly can be configured to excite a process gas in the process chamber 6 to form a plasma. The power adjustment assembly can be configured to detect a bias voltage value (e.g., a direct current bias voltage, i.e., DC Bias) on an upper surface of the chuck 9 in real-time, and calculate a difference between the bias voltage value and a target bias voltage value, and when the difference is greater than a preset threshold, adjust an output power value of the upper electrode assembly according to the difference until the difference is less than or equal to the preset threshold.

The inventor of the present disclosure has found through research that the bias voltage value on the upper surface of the chuck 9 can accurately reflect the density of the plasma 10 above the chuck 9 (i.e., an ion density in the plasma 10) in real-time. Specifically, according to a Poisson equation, an expression of the plasma sheath voltage V(t) with time can be obtained as:

$$V ( t ) = - \frac{{I}_{0}^{2}}{2 {ε}_{0} e n {ω}^{2} {A}^{2}} ( 1 - sin ω t )$$

where, I₀ denotes an amplitude of the RF current received by a lower electrode on the chuck 9, ε₀ denotes a dielectric constant, e denotes an amount of electrons, ω denotes an angular frequency of an RF signal received by the lower electrode, n denotes the density of the plasma 10 (i.e., the ion density), and A denotes a plate area of the lower electrode. It can be seen from the above expression that when the lower RF current amplitude I₀, the angular frequency ω, and the plate area A remain unchanged, the plasma sheath voltage V(t) and the plasma density n (and coupled power of an upper electrode 5) are inversely proportional.

The sheath voltage V(t) can be directly related to the bias voltage value on the upper surface of the chuck 9 and have a same changing trend as the bias voltage value. Therefore, by only detecting the bias voltage value on the upper surface of the chuck 9 in real-time, whether the plasma density n is in a normal range can be determined according to the bias voltage value.

In embodiments of the present disclosure, the structure of the upper electrode assembly is not specifically limited. For example, the upper electrode assembly can include an RF power supply 1 and an upper electrode 5. The upper electrode 5 can be, for example, a coil. The power adjustment assembly can be configured to change the amplitude of the current on the upper electrode 5 by adjusting the power of the RF power supply 1 (i.e., an output power value of the upper electrode assembly) to control the plasma density.

In the semiconductor process apparatus of embodiments of the present disclosure, the power adjustment assembly can be configured to detect the bias voltage value on the upper surface of the chuck 9 in real-time, calculate the difference between the bias voltage value and the target bias voltage value, and determine whether the plasma density currently in the process chamber is normal by determining whether the difference exceeds the preset threshold, and when the difference is greater than the preset threshold, automatically adjust the output power of the upper electrode assembly is automatically adjusted according to the difference. Therefore, in embodiments of the present disclosure, a density state of the plasma can be characterized by detecting the bias voltage value, and real-time feedback adjustment can be performed to accurately control the plasma density in the semiconductor process to compensate for the differences caused by inconsistency of hardware such as the coils and the dielectric windows to improve process consistency between different process chambers.

In addition, in the semiconductor process apparatus of embodiments of the present disclosure, the power adjustment assembly can be configured to directly adjust the output power value of the upper electrode assembly in real-time according to the density n of the plasma 10 without considering the impact of other structures in the process chamber on the plasma density. For example, the plasma density n can be changed by adjusting the output power of the upper electrode assembly when the power of the lower electrode remains unchanged. In addition, embodiments of the present disclosure can be applied to insulation and non-insulation chuck structures arranged in the process chamber 6 and can be applied to ICP RF plasma sources of 13.56 MHz and other frequencies.

In embodiments of the present disclosure, how the power adjustment assembly adjusts the output power of the upper electrode assembly according to the difference is not specifically limited. For example, in some embodiments, as shown in FIG. 1, the power adjustment assembly includes a voltage comparator 12 and a voltage sensor 131.

The voltage sensor 131 can be configured to detect the bias voltage value on the upper surface of the chuck 9 in real-time and send the bias voltage value to the voltage comparator 12.

The voltage comparator 12 can be configured to calculate the difference between the bias voltage value and the target bias voltage value V0, and when the difference is greater than the preset threshold, compare the bias voltage value to the target bias voltage value V0. If the bias voltage value is lower than the target bias voltage value V0 (i.e., the density n of the plasma 10 higher than a preset standard), the output power of the upper electrode assembly can be reduced to reduce the density n of the plasma 10. If the bias voltage value is higher than the target bias voltage value V0 (i.e., the ion density n of the plasma 10 lower than the preset standard), the output power of the upper electrode assembly can be increased to increase the density n of the plasma 10.

By considering an accuracy error in voltage detection, to avoid frequent adjustment when the bias voltage value is close to the target bias voltage value V0, preferably, the voltage comparator 12 can maintain the output power of the upper electrode assembly unchanged when the difference is smaller than or equal to the preset threshold.

The preset threshold can be an allowable accuracy range around the target bias voltage V0. That is, the preset threshold can be ΔVth in V0±ΔVth. In embodiments of the present disclosure, a value of the preset threshold ΔVth is not specifically limited. For example, in some embodiments, the preset threshold ΔVth can be 1% of the target bias voltage value V0. That is, the voltage comparator 12 can maintain the output power of the upper electrode assembly unchanged when the bias voltage is within an interval of (1±1%)V0.

To improve the power adjustment efficiency of the upper electrode assembly, in some embodiments, an adjustment amplitude of the output power of the upper electrode assembly adjusted by the power adjustment assembly can be positively correlated with the difference ΔV between the bias voltage value and the target bias voltage value V0. Thus, when the difference ΔV is relatively large (i.e., when the density n of the plasma 10 differs greatly from the preset standard), the output power of the upper electrode assembly can be adjusted in a larger range to improve the adjustment efficiency.

To simplify calculation steps and further improve the adjustment efficiency, in some embodiments, the voltage comparator 12 can be configured to determine an adjustment amplitude corresponding to the difference according to a difference interval corresponding to the difference and a correspondence between the preset difference interval and the adjustment amplitude, and adjust the output power of the upper electrode assembly according to the adjustment amplitude.

In embodiments of the present disclosure, how to divide the difference interval is not specifically limited. For example, to facilitate a skilled person to understand, as an optional embodiment of the present disclosure, the correspondence of the difference interval and the adjustment amplitude can include:
a first difference interval, the above difference |ΔV| being greater than or equal to 50% of the target bias voltage value V0, i.e., |ΔV|≥50%×V0;
a second difference interval, the above difference |ΔV| being greater than or equal to 20% of the target bias voltage value V0 and less than 50% of the target bias voltage value V0, i.e., 20%×V0≤|ΔV|<50%×V0;
a third difference interval, the above difference |ΔV| being greater than or equal to 5% of the target bias voltage value V0 and less than 20% of the target bias voltage value V0, i.e., 5%×V0≤|ΔV|<20%×V0; and
a fourth difference interval, the above difference |ΔV| being greater than or equal to 1% of the target bias voltage value V0 and less than 5% of the target bias voltage value V0, i.e., 1%×V0≤|ΔV|<5%×V0.

The first adjustment amplitude corresponding to the first difference interval can be larger than the second adjustment amplitude corresponding to the second difference interval. The second adjustment amplitude can be larger than the third adjustment amplitude corresponding to the third difference interval. The third adjustment amplitude can be larger than the fourth adjustment amplitude corresponding to the fourth difference interval.

In embodiments of the present disclosure, the preset adjustment amplitude (i.e., an adjustment step ΔP of the output power of the upper electrode assembly) corresponding to each difference interval is not specifically limited. For example, as an optional embodiment of the present disclosure, the first adjustment amplitude can be greater than or equal to 50 W, the second adjustment amplitude can be greater than or equal to 20 W, the third adjustment amplitude can be greater than or equal to 5 W, and the fourth adjustment amplitude can be greater than or equal to 1 W.

In some embodiments, the voltage comparator 12 can be configured to adjust the output power of the upper electrode assembly according to a step size of 50 W when the difference is in the above first difference interval, adjust the output power of the upper electrode assembly according to a step size of 20 W when the difference is in the above second difference interval, adjust the output power of the upper electrode assembly according to a step size of 5 W when the difference is in the above third difference interval, and adjust the output power of the upper electrode assembly according to a step size of 1 W when the difference is in the above fourth difference interval.

In embodiments of the present disclosure, other structures in the semiconductor process apparatus are not specifically limited. For example, as shown in FIG. 1, the RF power supply 1 loads power to the upper electrode 5 (e.g., a coupled coil) through a matching device 2. The process gas can enter the process chamber 6 (related members such as a liner and a focus ring of the process chamber are not shown) through a nozzle 11 mounted at the quartz dielectric window 7. Meanwhile, RF energy on the upper electrode 5 can be coupled to the process chamber 6 through the dielectric window 7. The plasma 10 can be generated and act on the wafer 8. The wafer 8 can be arranged on the chuck 9. The bias RF power supply 4 can load the RF energy on an RF copper column arranged at a bottom of the chuck 9 through the matching device 3. Thus, an RF field can be provided, and an RF bias voltage can be generated to form an ion acceleration sheath on the wafer surface to etch the wafer 8.

In some embodiments, as shown in FIG. 1, the power adjustment assembly further includes an analog-to-digital converter 132. The voltage sensor 131 can be configured to detect the bias voltage value on the chuck 9 in real-time and output the detected bias voltage value to the analog-to-digital converter 132 in an analog signal format. The analog-to-digital converter 132 can have an analog-to-digital conversion function and can be configured to convert the bias voltage value sent by the voltage sensor 131 in the analog signal format into a digital signal and transfer the digital signal to a voltage comparator 12.

In embodiments of the present disclosure, the structure type of the chuck 9 is not specifically limited. For example, as an optional embodiment of the present disclosure, when the upper surface of the chuck 9 is an upper surface made of a ceramic material layer, the voltage sensor 131 can be an RF voltage sensor configured to detect the RF voltage value of the ceramic material layer in real-time, and convert the RF voltage value into the bias voltage value according to the preset correspondence between the RF voltage value and the bias voltage value.

Specifically, the RF voltage sensor can detect the RF voltage signal Vpp closest to the upper surface of the chuck in real-time to represent the bias voltage value above the wafer. The analog-to-digital converter 132 can be configured to convert the RF signal collected by the RF voltage sensor into detection voltage information and transfer the detection voltage information to the voltage comparator 12.

As an optional embodiment of the present disclosure, when the upper surface of the chuck 9 is an upper surface made of a metal layer, the voltage sensor 131 can be a DC voltage sensor and configured to detect the DC voltage value of the metal layer in real-time. The DC voltage value can be the bias voltage value. Correspondingly, the analog-to-digital converter 132 can be configured to convert the analog signal detected by the DC voltage sensor into a digital signal and transfer the digital signal to the voltage comparator 12.

As another technical solution, the present disclosure further provides a power control method, which is applied to the above semiconductor process apparatus of the present disclosure. The power control method includes the following processes.

At S1, after the upper electrode assembly excites the process gas in the process chamber to form the plasma, the bias voltage value on the upper surface of the chuck is detected in real-time.

At S2, the difference between the bias voltage value and the target bias voltage value is calculated, and when the difference is greater than the preset threshold, the output power of the upper electrode assembly is adjusted according to the difference until the difference is less than or equal to the preset threshold.

In embodiments of the present disclosure, the output power of the upper electrode assembly can be directly adjusted in real-time according to the above difference without considering the impact of the other structures in the process chamber on the plasma density. For example, when the lower electrode power is unchanged, the plasma density can be changed by adjusting the output power of the upper electrode assembly.

In some optional embodiments, step S2 specifically includes:
calculating the difference between the bias voltage value and the target bias voltage value, and when the difference is greater than the preset threshold, comparing the bias voltage value to the target bias voltage value, if the bias voltage value is lower than the target bias voltage value, reducing the output power of the upper electrode assembly, if the bias voltage value is higher than the target bias voltage value, increasing the output power value of the upper electrode assembly, and when the difference is less than or equal to the preset threshold, maintaining the output power of the upper electrode assembly unchanged. Thus, the frequent adjustments can be avoided caused by the accuracy error of the voltage detection when the bias voltage value is close to the target bias voltage value.

In some optional embodiments, the adjustment amplitude for adjusting the output power of the upper electrode assembly can be positively related to the difference between the bias voltage value and the target bias voltage value. That is, when the difference is large (i.e., when the plasma density differs greatly from the preset standard), the output power of the upper electrode assembly can be adjusted with a larger amplitude to improve the power adjustment efficiency of the upper electrode assembly.

In some optional embodiments, to simplify the calculation steps and further improve the adjustment efficiency, the adjustment amplitude corresponding to the difference can be determined according to the difference interval corresponding to the difference interval and the preset correspondence between the difference interval and the adjustment amplitude. The output power of the upper electrode assembly can be adjusted according to the adjustment amplitude.

For example, the correspondence between the difference interval and the adjustment amplitude specifically includes:
a first difference interval, the above difference |ΔV| being greater than or equal to 50% of the target bias voltage value V0, i.e., |ΔV|≥%50%×V0;
a second difference interval, the above difference |ΔV| being greater than or equal to 20% of the target bias voltage value V0 and less than 50% of the target bias voltage value V0, i.e., 20%×V0≤|ΔV|<50%×V0;
a third difference interval, the above difference |ΔV| being greater than or equal to 5% of the target bias voltage value V0 and less than 20% of the target bias voltage value V0, i.e., 5%×V0≤|ΔV|<20%×V0; and
a fourth difference interval, the above difference |ΔV| being greater than or equal to 1% of the target bias voltage value V0 and less than 5% of the target bias voltage value V0, i.e., 1%×V0≤|ΔV|<5%×V0.

The first adjustment amplitude corresponding to the first difference interval can be larger than the second adjustment amplitude corresponding to the second difference interval. The second adjustment amplitude can be larger than the third adjustment amplitude corresponding to the third difference interval. The third adjustment amplitude can be larger than the fourth adjustment amplitude corresponding to the fourth difference interval.

In the power control method of the present disclosure, the density state of the plasma can be characterized by detecting the bias voltage value, and the feedback adjustment can be performed in real-time to accurately control the plasma density in the semiconductor process and compensate for the differences caused by the inconsistency of the hardware such as the coils and the dielectric windows. Thus, the process consistency can be improved between different process chambers.

It can be understood that the above embodiments are only exemplary embodiments used to illustrate the principle of the present disclosure. However, the present disclosure is not limited to this. For those skilled in the art, without departing from the spirit and essence of the present disclosure, various modifications and improvements can be made. These modifications and improvements are also within the scope of the present disclosure.

1. A semiconductor process apparatus, comprising:
a process chamber including a chuck configured to carry a wafer;
an upper electrode assembly configured to excite a process gas in the process chamber to form a plasma; and
a power adjustment assembly configured to detect a bias voltage value on an upper surface of the chuck in real-time, calculate a difference between the bias voltage value and a target bias voltage value, and in response to the difference being greater than a preset threshold, adjust output power of the upper electrode assembly according to the difference until the difference is less than or equal to the preset threshold.

2. The semiconductor process apparatus of claim 1, wherein the power adjustment assembly includes:
a voltage sensor configured to detect the bias voltage value on the upper surface of the chuck in real-time and transfer the bias voltage value to a voltage comparator; and
the voltage comparator configured to calculate the difference between the bias voltage value and the target bias voltage value, and in response to the difference being greater than the preset threshold, compare the bias voltage value to the target bias voltage value, in response to the bias voltage value being lower than the target bias voltage value, reduce the output power of the upper electrode assembly, in response to the bias voltage value being higher than the target bias voltage value, increase the output power value of the upper electrode assembly, and in response to the difference being less than or equal to the preset threshold, maintain the output power of the upper electrode assembly unchanged.

3. The semiconductor process apparatus according to claim 2, wherein an adjustment amplitude of the output power of the upper electrode assembly adjusted by the voltage comparator and the difference between the bias voltage value and the target bias voltage value is positively correlated.

4. The semiconductor process apparatus according to claim 3, wherein the voltage comparator is configured to:
determine the adjustment amplitude corresponding to the difference according to a difference interval corresponding to the difference and a preset correspondence between the difference interval and the adjustment amplitudes; and
adjust the output power of the upper electrode assembly according to the adjustment amplitude.

5. The semiconductor process apparatus according to claim 4, wherein the correspondence between the difference interval and the adjustment amplitude includes:
a first difference interval, the difference being greater than or equal to 50% of the target bias voltage value;
a second difference interval, the difference being greater than or equal to 20% of the target bias voltage value and less than 50% of the target bias voltage value;
a third difference interval, the difference being greater than or equal to 5% of the target bias voltage value and less than 20% of the target bias voltage value; and
a fourth difference interval, the difference being greater than or equal to 1% of the target bias voltage value and less than 5% of the target bias voltage value;
wherein:
a first adjustment amplitude corresponding to the first difference interval is larger than a second adjustment amplitude corresponding to the second difference interval;
the second adjustment amplitude is larger than a third adjustment amplitude corresponding to the third difference interval; and
the third adjustment amplitude is greater than a fourth adjustment amplitude corresponding to the fourth difference interval.

6. The semiconductor process apparatus according to claim 5, wherein:
the first adjustment amplitude is greater than or equal to 50 W;
the second adjustment amplitude is greater than or equal to 20 W;
the third adjustment amplitude is greater than or equal to 5 W; and
the fourth adjustment amplitude is greater than or equal to 1 W.

7. The semiconductor process apparatus according to claim 1, wherein the preset threshold is 1% of the target bias voltage value.

8. The semiconductor process apparatus according to claim 2, wherein:
when the upper surface of the chuck is an upper surface made of a ceramic material layer, the voltage sensor is configured to detect an RF voltage value of the ceramic material layer in real-time and convert the RF voltage value into the bias voltage value according to a correspondence between the RF voltage value and the bias voltage value.

9. The semiconductor process apparatus according to claim 2, wherein:
when the upper surface of the chuck is an upper surface made of a metal layer, the voltage sensor is configured to detect a DC voltage an upper surface of the metal layer in real-time, the DC voltage being the bias voltage value.

10. The semiconductor process apparatus according to claim 2, wherein the power adjustment assembly further includes:
an analog-to-digital converter configured to convert the bias voltage value transferred by the voltage sensor in an analog signal into a digital signal and transfer the digital signal to the voltage comparator.

11. A power control method comprising:
after a process gas in a process chamber is excited to form a plasma, detecting a bias voltage value on an upper surface of a chuck in real-time; and
calculating a difference between the bias voltage value and a target bias voltage value, and in response to the difference being greater than a preset threshold, adjusting output power value of an upper electrode assembly according to the difference until the difference is less than or equal to the preset threshold.

12. The power control method according to claim 11, wherein calculating the difference between the bias voltage value and the target bias voltage value, and in response to the difference being greater than the preset threshold, adjusting the output power of the upper electrode assembly according to the difference until the difference is less than or equal to the preset threshold includes:
calculating the difference between the bias voltage value and the target bias voltage value;
in response to the difference being greater than the preset threshold, comparing the bias voltage value to the target bias voltage value;
in response to the bias voltage value being lower than the target bias voltage value, reducing the output power of the upper electrode assembly;
in response to the bias voltage value being higher than the target bias voltage value, increasing the output power of the electrode assembly; and
in response to the difference being less than or equal to the preset threshold, maintaining the output power value of the upper electrode assembly unchanged.

13. The power control method according to claim 12, wherein an adjustment amplitude for adjusting the output power of the upper electrode assembly and the difference between the bias voltage value and the target bias voltage value are positively correlated.

14. The power control method according to claim 13, wherein:
the adjustment amplitude corresponding to the difference is determined according to an difference interval corresponding to the difference and a preset correspondence between the difference interval and the adjustment amplitude; and
the output power of the upper electrode assembly is adjusted according to the adjustment amplitude.

15. The power control method according to claim 14, wherein the correspondence between the difference interval and the adjustment amplitude includes:
a first difference interval, the difference being greater than or equal to 50% of the target bias voltage value;
a second difference interval, the difference being greater than or equal to 20% of the target bias voltage value and less than 50% of the target bias voltage value;
a third difference interval, the difference being greater than or equal to 5% of the target bias voltage value and less than 20% of the target bias voltage value; and
a fourth difference interval, the difference being greater than or equal to 1% of the target bias voltage value and less than 5% of the target bias voltage value;
wherein:
a first adjustment amplitude corresponding to the first difference interval is larger than a second adjustment amplitude corresponding to the second difference interval;
the second adjustment amplitude is larger than a third adjustment amplitude corresponding to the third difference interval; and
the third adjustment amplitude is greater than a fourth adjustment amplitude corresponding to the fourth difference interval.

16. The power control method according to claim 15, wherein:
the first adjustment amplitude is greater than or equal to 50 W;
the second adjustment amplitude is greater than or equal to 20 W;
the third adjustment amplitude is greater than or equal to 5 W; and
the fourth adjustment amplitude is greater than or equal to 1 W.

17. The power control method according to claim 11, wherein the preset threshold is 1% of the target bias voltage value.

18. The power control method according to claim 11, further comprising:
in response to the upper surface of the chuck being an upper surface made of a ceramic material layer, detecting an RF voltage value of the ceramic material layer in real-time and converting the RF voltage value into the bias voltage value according to a correspondence between the RF voltage value and the bias voltage value.

19. The power control method according to claim 11, wherein:
in response to the upper surface of the chuck being an upper surface made of a metal layer, detecting a DC voltage an upper surface of the metal layer in real-time, the DC voltage being the bias voltage value.

20. The power control method according to claim 11, further comprising:
converting the bias voltage value transferred by a voltage sensor in an analog signal into a digital signal and transferring the digital signal to a voltage comparator.
